(19) United States
(12) Patent Application Publication
(10) Pub. No.: US 2010/0330799 A1
(43) Pub. Date: Dec. 30, 2010

(54) SEMICONDUCTOR DEVICE AND PROCESS FOR PRODUCING THE SAME

(75) Inventors: Nobuaki HAMANAKA, Kanagawa (JP); Yoshiko KASAMA, Kanagawa (JP)

Correspondence Address: YOUNG & THOMPSON, 209 Madison Street, Suite 500, Alexandria, VA, 22314, US

(73) Assignee: RENESAS ELECTRONICS CORPORATION, Kawasaki-shi (JP)

(21) Appl. No.: 12/823,536

(22) Filed: Jun. 25, 2010

(30) Foreign Application Priority Data
Jun. 26, 2009 (JP) 152982/09

(51) Int. Cl. H01L 21/768

(52) U.S. Cl. 438/618; 257/E21.585

(57) ABSTRACT

Improved control over formation of low k air gaps in interlayer insulating films is achieved by plasma pretreatment of the region of the insulating film to be removed. The intended air gap region is exposed through a mask while the film region to be preserved is shielded by the mask. The intended air gap region is then exposed to a plasma so as to render it more susceptible to removal in a subsequent treatment. One or more Cu interconnects are embedded in both regions of the insulator film. The insulator film in the intended air gap region is then selectively removed to form air gaps adjacent a Cu interconnect in that region.

### BACKGROUND OF THE INVENTION

The present invention relates to a method for fabricating a semiconductor device and to the semiconductor device thus made.

The operating speed of various semiconductor devices can be limited by signal propagation delay through interconnects in the devices. The delay constant of an interconnect is a function of the interconnect resistance multiplied by the capacitance between interconnects. A reduction in capacitance between interconnects can therefore improve the operating speed of such devices.

As chip sizes continue to decrease, lower-layer interconnects must be formed at ever-decreasing smaller pitches. Accordingly, high capacitance between lower-layer interconnects is causing significant problems such as crosstalk between interconnects and an increase in power consumption due to an increase in transistor parasitic capacitance.

A low-resistance interconnection technique, the so-called damascene method, is being widely used to form a multilayer copper interconnection structure. In the damascene method, an insulator film formed between interconnect layers is dry etched based on a pattern formed by lithography in the process of forming interconnect layers on top of one another. Since the interlayer insulator film functions like a mold in the process for forming copper interconnects, vacancies can be formed in the insulator film to reduce the k-value (relative dielectric constant) or air gaps can be formed by removing the insulator film after formation of the interconnects, thereby reducing the capacitance between the interconnects.

“Proceedings of IITC 2008, p. 196 (R. Gras et al.)” describes the following method for forming air gaps. First, an interconnect layer is formed by the damascene method using a silicon oxide (SiO₂) film as an interlayer insulator film. Then, a thin SiCN film is formed on the interconnect layer. A photoresist is formed on the SiCN layer and is used to pattern chemical injection inlets. The chemical injection holes are formed by dry etching, then the photoresist is removed, and hydrofluoric acid (HF) is injected through the surface of the wafer to dissolve the SiO₂ film to form air gaps. Then, an upper interconnect layer is formed.

Japanese Patent Laid-Open Publication No. 2008-166726 discloses a technique that provides air gaps only in regions where air gaps are required, thereby minimizing reduction in mechanical strength caused by air gaps.

However, the present inventors have found the following problems with these conventional techniques. The technique described in Japanese Patent Laid-Open Publication No. 2008-166726 requires a metal ring that separates a region where an air gap is to be formed from a region where an air gap is not to be formed. Erosion can occur around the metal ring in a CMP (Chemical Mechanical Polishing) process. Therefore, the technique has the design constraint that in order to meet specifications for resistance in interconnects made of a metal such as copper, the interconnects need to be provided at a predetermined distance or farther from the metal ring.

Furthermore, if plasma processing follows the formation of the metal ring, the ring can be broken by accumulation of charged particles derived from the plasma. Consequently, the metal can diffuse into surrounding regions. Diffused metal can attach to a near interconnect to cause a short circuit. If the metal ring is small, a vortex magnetic field can be generated inside the ring in the process of accumulation of charged particles described above. The vortex magnetic field can affect operation of the transistor through an interconnect inside the ring.

Even more, if air gaps in the insulator film between lower-layer interconnects are too large, the mechanical strength of the interconnects becomes insufficient. When solder bumps are formed on the interconnects in which air gaps are formed or bonding wires are connected to the interconnect, a strong pressure is exerted on the interconnects. The pressure can cause a problem such as pattern collapse in an interconnect immediately below the solder bumps or bonding wires. Therefore, there is a need for a process that removes an insulator film only from regions where a low capacitance between interconnects is required while leaving the insulator film in regions in the same lower interconnect layer where a mechanically strong structure is required.

### SUMMARY

According to one aspect of the present invention, there is provided a semiconductor device fabrication method including the steps of:

forming a mask film on an insulator film overlying a substrate;

removing the mask from a first region of the insulator film while leaving the mask in a second region of the insulator film;

exposing the first region to a plasma while the mask shields the second region, so as to render the first region more susceptible to removal by a subsequent treatment;

removing the mask film from the second region;

forming at least one metal interconnect in each of the first and second regions; and

selectively removing the first region to form an air gap adjacent a metal interconnect formed in the first region, while preserving the second region.

According to the present invention, particular regions of an insulator film are covered with a mask film and regions that are not covered with the mask film are selectively processed by plasma processing. This can increase the etching rate of the insulator film in the regions processed by the plasma relative to the regions not processed by the plasma. Accordingly, the insulator film can be selectively removed from the regions processed by the plasma to form air gaps while the insulator film can be left in the regions where mechanical strength is required. Consequently, a semiconductor device capable of high-speed operation can be fabricated with a high yield.

### BRIEF DESCRIPTION OF THE DRAWINGS

The above and other objects, advantages and features of the present invention will be more apparent from the following description taken in conjunction with the accompanying drawings, in which:

FIGS. 1A and 1B are a diagrams illustrating a semiconductor device fabrication method according to an embodiment;

FIGS. 2C and 2D are a diagrams illustrating the semiconductor device fabrication method according to the embodiment;

FIGS. 3E and 3F are a diagrams illustrating the semiconductor device fabrication method according to the embodiment;

FIGS. 4G and 4H are a diagrams illustrating the semiconductor device fabrication method according to the present embodiment;

FIG. 5 is a schematic cross-sectional view of a semiconductor device according to an embodiment;

FIG. 6 is a schematic cross-sectional view of the semiconductor device according to an embodiment;

FIG. 7 is a plan view of an interconnect structure of a semiconductor device according to the embodiment;

FIGS. 8A AND 8B are plan views of the interconnect structure of the semiconductor device according to an embodiment;

FIG. 9 is a diagram showing results of a study of a practical example;

FIG. 10 is a diagram showing results of a study of another practical example; and

FIG. 11 is a diagram showing results of a study of yet another practical example.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be described below with reference to the accompanying drawings. Like components are labeled like reference numerals throughout the drawings and repeated description of components will be omitted as appropriate.

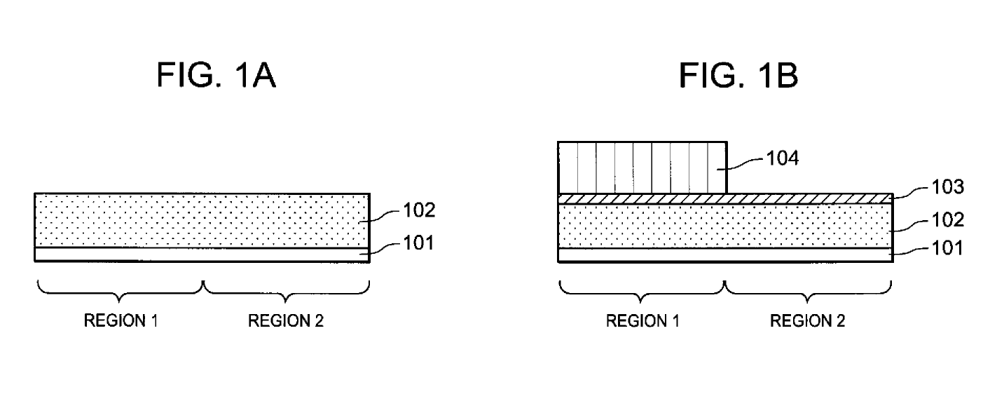

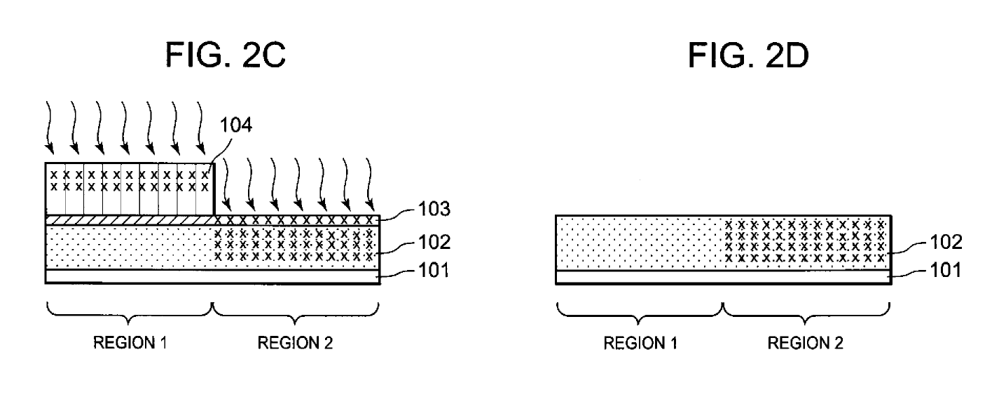

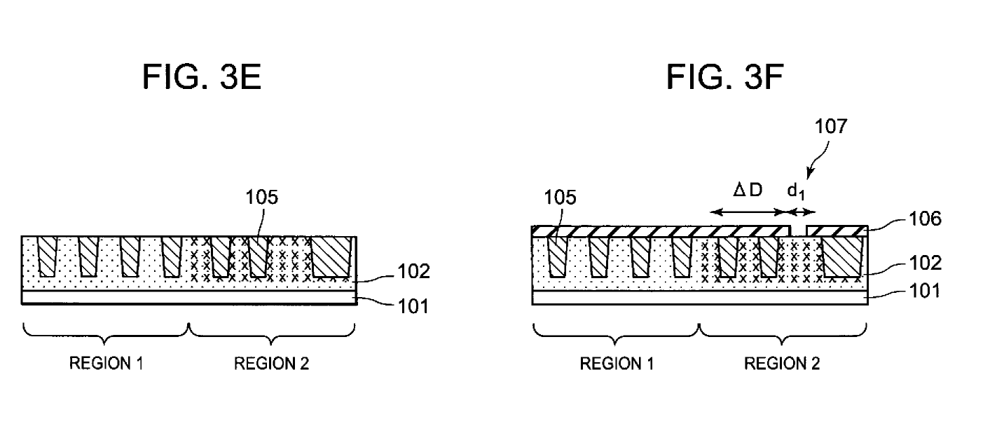

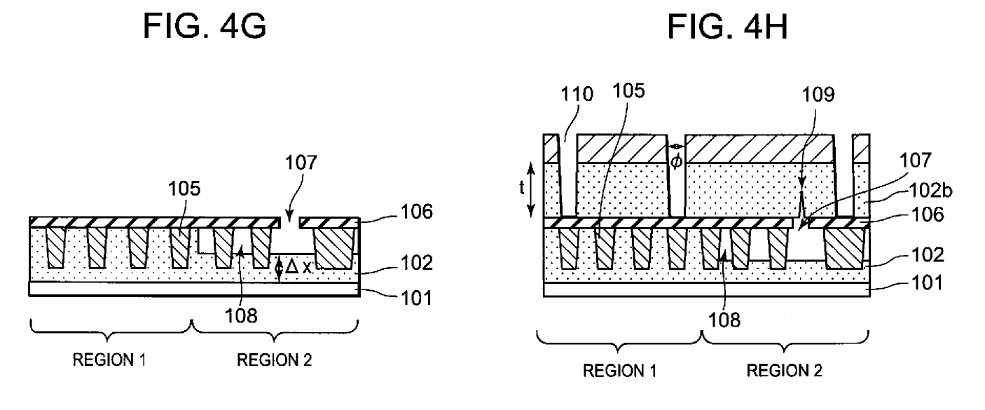

FIGS. 1 through 4 are diagrams illustrating a semiconductor device fabrication method according to an embodiment of the present invention. The semiconductor device fabrication method according to the present embodiment includes the step of providing an insulator film 102 in which region 1 (a film region) where an air gap is not to be formed and region 2 (an air gap region) where an air gap is to be formed (FIG. 1A), the step of covering the surface of region 1 with a photoresist 104 (mask film) (FIG. 1B), the step of applying plasma processing to region 2 of the insulator film 102 with region 1 being covered with the photoresist 104 (FIG. 2C), the step of removing the photoresist 104 from the insulator film 102 exposed to the plasma processing (FIG. 2D), the step of embedding a copper (Cu) interconnect 105 (metal interconnect) in regions 1 and 2 of the insulator film 102 from which the photoresist 104 has been removed (FIG. 3E), and the step of removing the insulator film 102 from region 2 processed by the plasma processing to form an air gap 108 along the sides of the Cu interconnect 105 (FIG. 4G).

The steps will be described below in detail.

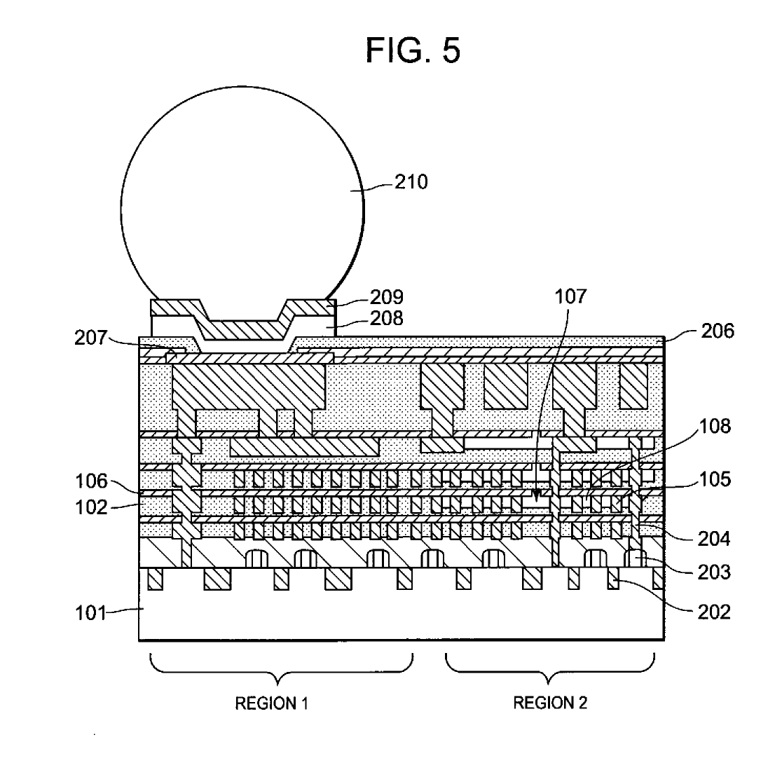

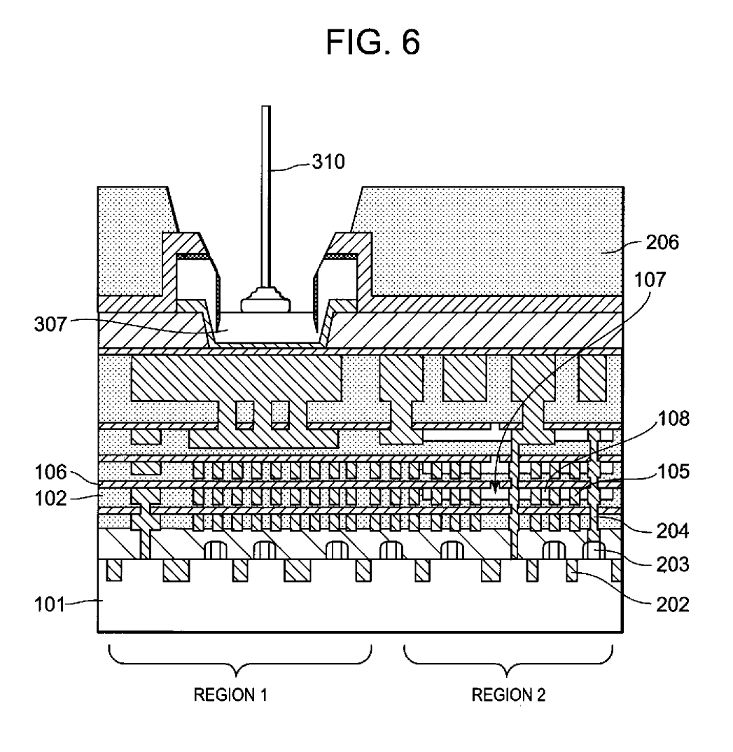

First, an insulator film 102 is formed on a substrate 101 as depicted in FIG. 1A. While a transistor is formed on the substrate 101 as depicted in FIGS. 5 and 6, the transistor is omitted from FIGS. 1 through 4. The insulator film 102 is a SiOC film including Si—O bonds and Si—C bonds and having a k-value (relative dielectric constant) of 2.7 or less. Specifically, the insulator film 102 is preferably a SiOC film having a low Si—O bond energy and a high porosity. More specifically, the insulator film 102 may be a film of Black Diamond such as BD (with a k of 2.35), BD 2.7 (with a k of 2.4), or BD2x (with a k of 2.5), an organic silica film using cyclic siloxane such as OMCTS (Octamethylcyclotetrasiloxane, [(CH₃)₂SiO]₄), or a porous silica film such as a p-SiCOH film. The insulator film 102 is formed to a thickness in the range of 100 nm to 1000 nm, for example.

Then an intermediate layer 103 that has an affinity for the photoresist 104 is formed on the insulator film 102. The formation of the intermediate layer 103 can improve the wettability of the photoresist 104. The intermediate layer 103 is preferably formed to a thickness of less than or equal to 50 nm. This can cause plasma to penetrate into the insulator film 102 through the intermediate layer 103 in plasma processing, which will be described later. The intermediate layer 103 may be a SiC, SiCN, or SiO₂ film. In particular, SOG (Spin On Glass) and a low-temperature oxide film deposited at a temperature less than or equal to 250° C.

Then the surface of the intermediate layer 103 is coated with a photoresist 104. The density of the photoresist 104 may be greater than that of the insulator film 102. This is because vacancies are formed in the insulator film 102 to reduce the relative dielectric constant. The thickness of the photoresist 104 is approximately the same as the thickness of the insulator film 102. Then, exposure and development is performed to pattern the photoresist 104 to leave the photoresist 104 only in region 1 (FIG. 1B).

Then, the surface of the photoresist 104 in region 1 and the surface of the intermediate layer 103 in region 2 are exposed to plasma (FIG. 2C). Specifically, the plasma processing is applied to the insulator film 102 perpendicularly to the surface of the wafer. The plasma source may be a noble gas such as helium, neon or argon, or ammonium gas. Plasma applied to the surface of the intermediate layer 103 penetrates into the insulator film 102 through the intermediate layer 103. On the other hand, the insulator film 102 in region 1 is protected by the photoresist 104 and therefore is not processed by the plasma. Accordingly, properties of only the insulator film 102 in region 2 can be modified. The plasma penetration distance can be controlled by designing the plasma source, plasma exposure time, and applied power according to the type of the material of the insulator film 102. Consequently, the insulator film 102 can be modified up to a desired depth. Plasma is controlled to penetrate to a distance less than or equal to the thickness of the photoresist 104.

The photoresist 104 is ashed and then the intermediate layer 103 is removed by etch back (FIG. 2D).

Interconnect trenches are formed in the insulator film 102 by conventional lithography and dry etching techniques. Then, Cu interconnects 105 are formed by damascene method using PVD (Physical Vapor Deposition), plating, and CMP (FIG. 3E).

A diffusion preventing film 106 is formed to cover the surface of the Cu interconnects 105 formed in regions 1 and 2. The diffusion preventing film 106 prevents diffusion of Cu from the Cu interconnects 105. The diffusion preventing film 106 may be a SiCN film or SiC film. The diffusion preventing film 106 is formed to a thickness in the range of 10 nm to 100 nm, for example.

Then, a photosensitive resist is used to pattern the diffusion preventing film 106 to open a portion of the diffusion preventing film 106 to form an injection inlet (opening) 107 for injecting an etching solution and expose the insulator film 102 at the bottom of the injection inlet 107 (FIG. 3F). The diameter d1 of the injection inlet 107 is preferably approximately 100 nm. The distance (ΔD) between the boundary between regions 1 and 2 to the periphery of the injection inlet 107 is preferably in the range of 0.5 μm to 1 μm.

Then, an etching solution is injected through the injection inlet 107 to etch away the insulator film 102. The etching solution may be hydrofluoric acid (HF) or a salt of HF. A salt of HF may be ammonium fluoride. The fluorine content of the etching solution is preferably 0.5% of the solution in mole percentage. The pH of the etching solution is preferably in the range of 1 to 8. Such an etching solution can minimize the surface roughness and grain-boundary corrosion due to oxidation of the Cu interconnects 105 in contact with the etching solution.

Since the diffusion preventing film 106 includes Si—C bonds, the diffusion preventing film 106 resists etching with HF. Properties of the region in the insulator film 102 processed with plasma are modified by the plasma to become easily etched. Accordingly, the insulator film 102 at the bottom of the injection inlet 107 is removed first.

On the other hand, the insulator film 102 in region 1 has not been processed by plasma and therefore resists etching. Accordingly, the etch rate decreases at the boundary between regions 1 and 2. Consequently, an air gap 108 can be formed only in region 2. By choosing the photoresist 104 to be greater than or equal to the depth of the air gaps 108 in the step in FIG. 2B, formation of an air gap 108 in region 1 can be prevented.

Properties of portions of the insulator film 102 in region 2 where plasma has not reached have not been modified and therefore the portions resist etching. Therefore, when the etching solution reaches the portions of region 2 that have not been processed by plasma, the etch rate drops. Accordingly, an air gap 108 can be formed to a desired thickness so as not to completely penetrate the insulator film 102. By forming the air gap 108 to a thickness less than the thickness of the insulator film 102, a required mechanical strength of the region 2 can be ensured.

Another insulator film 102b is formed on the diffusion preventing film 106 (FIG. 4H). The insulator film 102b can be made of any of the materials given as examples of the material of the insulator film 102. The thickness (t) of the insulator film 102b preferably meets the condition d1≦0.9×t, where d1 is the diameter of the injection inlet 107. As depicted in FIG. 4H, formation of the insulator film 102b over the air gap 108 forms a void 109. This is because CVD inherently conformally deposits material. The void 109, if too large, poses a problem such as reduction of mechanical strength. However, by ensuring a sufficient thickness of the insulator film 102b, formation of an excessively large void 109 can be prevented and thereby influences of the void 109 such as reduction of the mechanical strength can be reduced to a negligible level.

Then, the lithography process depicted in FIG. 1B and the plasma processing depicted in FIGS. 2C and 2D are repeated to form vias 110 in the insulator film 102b. The diameter (φ) of the via is in the range of 20 nm to 180 nm, for example, and the height of the via is in the range of 100 nm to 1500 nm, for example. Then, a Cu film is embedded to form a Cu interconnect having a height in the range of 50 nm to 1000 nm, for example.

The etching process depicted in FIGS. 3F and 4G is repeated and the process depicted in FIGS. 1B through 3G is repeated to form a multilayer interconnect structure on top of the insulator film 102. After forming the multilayer interconnect structure, electrode pads are formed in the top interconnect layer in region 1.

FIGS. 5 and 6 illustrate completed exemplary semiconductor devices. While omitted from FIGS. 1 to 4, multiple transistors are provided on the substrate 101. The transistors are isolated from each other by an element isolation layer 202. A gate electrode 203 is in contact 204 with a Cu interconnect 105. An interconnect layer including an insulator film 102, Cu interconnects 105 embedded in the insulator film 102, and air gaps 108 formed along the sides of the Cu interconnects 105 is formed on the transistors. Multiple such interconnect layers are stacked. An injection inlet 107 formed for injecting an etching solution remains in a diffusion preventing film 106 formed between the insulator film 102 and the upper interconnect layer. The injection inlet 107 is formed directly above the air gap 108 and is connected to the air gap 108. An electrode pad is formed in the top interconnect layer. No air gap 108 is formed in the insulator film 102 immediately beneath the interconnect layer in which the electrode pad is formed.

The electrode pad of the semiconductor device illustrated in FIG. 5 is formed by a metal multilayer film including a titanium layer 207, an aluminum layer 208 and a nickel layer 209 stacked in this order. A solder ball 210 is formed on the nickel layer 209 at the top. The solder ball 210 is connected to the interconnect layer through the metal multilayer film. An insulator layer 206 of a material such as polyimide is formed at the top of the interconnect layer.

In the semiconductor device illustrated in FIG. 6, a bonding pad 307 of a material such as aluminum is formed as an electrode pad. A bonding wire 310 is connected to the bonding pad 307. The bonding wire 310 is connected to the interconnect layer through the bonding pad 307 made of aluminum or other material. An insulator layer 206 of a material such as polyimide is formed at the top of the interconnect layer in FIG. 6.

Advantageous effects of the present embodiment will be described below. According to the fabrication method of the present embodiment, region 1 of the insulator film 102 is covered with the photoresist 104 and region 2 of the insulator film 102 that is not covered with the photoresist 104 is selectively processed with plasma. Accordingly, the etch rate of the insulator film 102 in region 2 processed by plasma can be increased relative to region 1. Therefore, the insulator film 102 in region 2 processed by plasma can be selectively removed to form an air gap 108 while the insulator film 102 can be left in a region where mechanical strength is required. Consequently, a semiconductor device capable of operating at a high speed can be fabricated with a high yield.

The advantageous effects of the present embodiment will be described below in further detail. It has been known that interconnect resistance can be reduced by forming air gaps. Therefore, it has been expected that semiconductor devices capable of operating at high speeds could be fabricated by forming air gaps. However, the air gaps formed have disadvantageously reduced the mechanical strength of interconnects.

For example, when external connection terminals are formed by solder balls, the underlying insulator film can come unstuck due to the difference in stress between the insulator film and the solder during heat treatment in the fabrication process or temperature change after shipment of the device. If an air gap having an area exceeding a certain limit is formed in the insulator film, separation of the insulator film due to variations in stress is accelerated. Therefore, there is a problem that a portion where a broad air gap is formed is likely to come unstuck.

When bonding wires are formed, a strong force is applied to the semiconductor device from above during bonding or test pad probing. The force is mostly applied to a portion immediately below the pad. Therefore, if an air gap is formed immediately below the bonding pad, the external force applied by probing can damage the underlying film of the semiconductor device.

To solve these problems, according to the present embodiment, a region (region 2) where an air gap 108 is to be formed and a region (region 1) where an air gap is not to be formed are provided in the insulator film 102 and photolithography, plasma processing and etching are applied in combination. As a result, an air gap 108 is formed only in region 2 processed by plasma and a distinct boundary can be formed between regions 1 and 2. Therefore, an electrode pad for connecting to an external package can be provided in region 1 where an air gap is not formed while the interconnect resistance in region 2 where an air gap 108 is formed can be reduced. Furthermore, since the depth of air gaps can be flexibly controlled by controlling conditions under which the plasma processing is performed, an air gap 108 can be formed in region 2 by trading off between the interconnect resistance and mechanical strength. In region 1 where no air gap is formed, the interconnect resistance can be reduced by forming an insulator film having a low k-value.

The advantageous effects of the present embodiment are provided probably because properties of the insulator film are modified by plasma processing. If the insulator film 102 is a SiOC film, Si—C bonds, which have especially weak bond energy, are physically broken by plasma processing and the insulator film 102 becomes a film formed with fewer Si—O bridges. The film has a high degree of solubility in HF whereas a film containing Si—C bonds does not dissolve in HF. This may be the reason why a high etch selectivity between the region processed by plasma and the region not processed by plasma can be provided. Furthermore, the depth in the film to which Si—C bonds can be broken by plasma processing may depend on the mass and energy of the plasma source. Therefore, by controlling the conditions under which plasma processing is performed, a region where Si—C bonds are not broken can be formed in the insulator film 102 and, as a result, an air gap 108 with a desired depth can be formed.

Since the method according to the present embodiment does not provide a metal ring for preventing lateral diffusion of an etching solution that is used in the method disclosed in Japanese Patent Laid-Open publication No. 2008-166726, the chip area can be reduced. Furthermore, since diffusion of the etching solution in the depth direction can be controlled, the mechanical strength of the interconnect 105 can be ensured without needing to provide a bilayer insulator film 102. Therefore, the capacitance between interconnects can be reduced and manufacturing costs, the amount of wastes, and plasma damage can also be reduced.

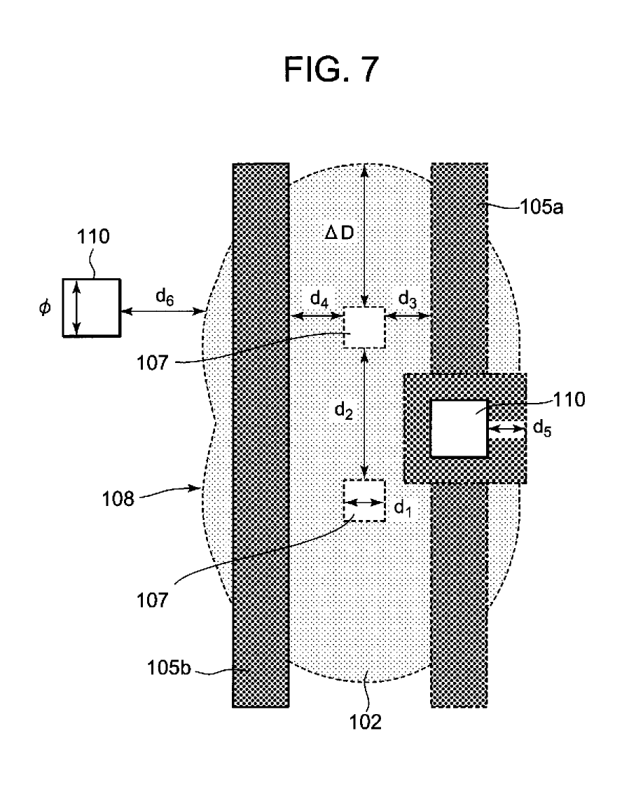

An exemplary design of an interconnect structure fabricated according to the present embodiment will be described with reference to drawings. FIG. 7 is a plan view of an interconnect structure fabricated according to the embodiment. A lower-layer interconnect 105a is a Cu interconnect formed in the same layer as an insulator film 102 in which an air gap 108 is formed. A via 110 is formed in the layer above the insulator film 102 in which the air gap 108 is formed. An upper-layer interconnect 105b is a Cu interconnect formed in the same layer as the via 110.

First, etching solution injection inlets 107 are preferably formed with a pitch (d2) of less than or equal to 1.0 μm. This allows the etching solution to be sufficiently diffused through the injection inlets 107 into the insulator film 102. As a result, an air gap 108 having a desired size can be formed.

The etching solution injection inlet 107 is preferably formed at a distance (ΔD) in the range of 0.5 μm to 1 μm from the boundary between region 1 where the air gap is not to be formed and region 2 where the air gap is to be formed. If the insulator film 102 is a SiOC film having vacancies, the density of the insulator film 102 itself is small and therefore the etching solution can also permeate into region 1 that has not been processed by plasma. If fluoride ions from the etching solution remain in the insulator film 102, the fluoride ions can diffuse during a subsequent heat treatment and cause corrosion of copper and dissolution of an interlayer film. To prevent the problem, penetration of the etching solution into region 1 where an air gap is not to be formed has to be prevented.

The present inventors have studied the diffusion distance of HF by using a SiOC film having a relative dielectric constant of 2.7 or less. The study has shown that the diffusion distance is 0.3 μm at maximum. Considering this result and the facts that the plasma processing proceeds laterally and that misalignments can occur in lithography processes in formation of a photoresist 104, formation of a Cu interconnect 105, and formation of etching solution injection inlets 107, penetration of the etching solution into region 1 can be prevented by providing a distance ΔD of greater than or equal to 0.5 μm. The etching solution can be well diffused in the region where an air gap is formed by choosing the distance ΔD to be less than or equal to 1 μm, as described above. The layout of the injection inlets 107 described above can provide an interconnect structure in which the distance (ΔD) between the periphery of an air gap 108 and the periphery of an injection inlet 107 is between or equal to 0.5 μm and 1 μm.

The distance (d3) between the periphery of the etching solution injection inlet 107 and the lower-layer interconnect 105a is preferably greater than or equal to 30 nm. Such a distance can prevent leakage of copper due to exposure of the surface of the lower-layer interconnect 105a.

The distance (d4) between the periphery of an etching solution injection inlet 107 and the upper-layer interconnect 105b is preferably greater than or equal to 30 nm. Formation of an insulator film 102 above the injection inlet 107 results in a void 109 formed immediately above the injection inlet 107 as depicted in FIG. 4H. If an interconnect trench is formed immediately above the injection inlet 107 by the damascene method, the void 109 will join the bottom of the trench of the upper-layer interconnect 105b. If this is the case, a hole is formed in the bottom of the interconnect trench and copper can leak through the hole. The leaking copper can come into contact with the lower-layer interconnect 105a through the air gap 108, an interlayer short circuit or an intralayer short circuit in the lower layer can occur. A distance d4 of 30 nm or greater can prevent the problem.

A via 110 formed above the air gap 108 overlaps the lower-layer interconnect 105a as viewed from above. The via 110 is preferably formed at a distance d5 greater than or equal to 30 nm from the periphery of the lower-layer interconnect 105a as viewed from above. Such a distance can prevent the via 110 from joining the air gap 108. For the same reason, a via 110 in region 1 where the air gap 108 is not formed is preferably formed at a distance d6 greater than or equal to 30 nm from the periphery of the air gap 108.

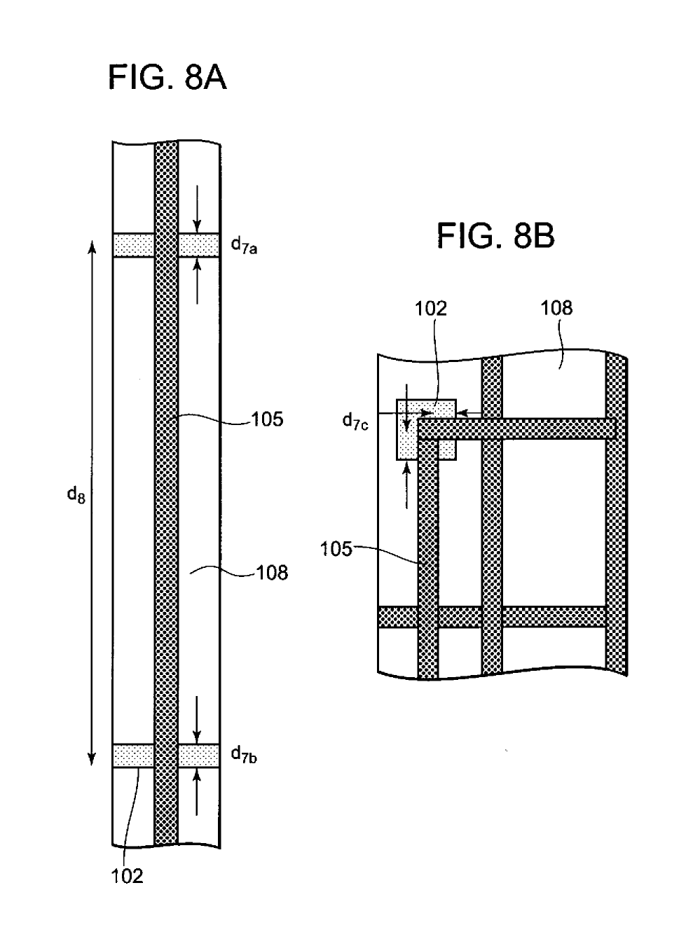

FIG. 8 is a plan view of an interconnect structure. If an interconnect 105 is formed across an air gap 108 as depicted, the air gap 108 is formed so that the insulator film 102 is left in predetermined locations. This can prevent reduction of the mechanical strength of the interconnect.

For example, if an interconnect 105 is extended across an air gap 108 as depicted in FIG. 8A, the interconnect 105 is divided into segments with a predetermined length (d8) and the insulator film 102 is left at both ends of each segment of the interconnect 105. The ratio between the length (d7a, d7b) of interconnect 105 embedded in the insulator film 102 and the length (d8-d7a-d7b) of the interconnect 105 raised over the air gap 108 can be controlled according to the width and depth of the interconnect 105. For example, if the depth of the interconnect 105 is 115 nm and the width is 50 nm, d8 is preferably less than or equal to 10 μm and each of d7a and d7b is preferably greater than or equal to 0.5 μm.

Preferably, the insulator film 102 is left at the sides of the ends of the interconnect 105. For example, in a section where interconnects 105 are bridged as illustrated in FIG. 8B, portions of insulator film 102 are left at the ends of interconnects 105 as illustrated. The distance d7c is preferably greater than or equal to 0.5 μm.

While embodiments of the present invention have been described above with reference to the drawings, they are illustrative of the present invention. Various other configurations may also be used.

### Practical Examples

### First Practical Example

In FIG. 1A, an insulator film 102 of BD2x (from Applied Materials, Inc.) was formed to a thickness of 200 nm. In FIG. 1B, an intermediate layer 103 of SOG (Spin On Glass) was to be formed on the insulator film 102 to a thickness of 50 nm at 200° C. The intermediate layer 103 was coated with a photoresist 104 to a thickness of 500 nm, followed by lithography for forming an air gap region 2. A plasma enhanced CVD system (Producer from Applied Materials, Inc.) was used to perform plasma processing with ammonium gas (NH₃) as the source at a power of 300 W and flow rate of 900 sccm under a gas pressure of 533 Pa (4.0 Torr) at 335° C. for 20 seconds with a distance between electrodes of 320 mils (FIG. 2C). The photoresist 104 was ashed and then the intermediate layer 103 was removed by etch back (FIG. 2D). A SiO₂ film was formed on the insulator film 102 and vias and interconnect trenches were formed by lithography and dry etching. Then, Cu interconnects 105 were formed by the damascene method using PVD, plating, and CMP to a thickness of 115 nm (FIG. 3E). A reduction of the thickness of the BD2x film during the process from formation of the insulator film 102 to the CMP was 30 nm. In a Cu interconnect 105 in region 2 in which an air gap 108 was to be formed and immediately above which a via 110 was to be formed, extensions of the Cu interconnect 105 are formed in all four X and Y directions to a length of 30 nm with respect to a diameter of the via 110 of 50 nm in the shape of a hammerhead. A diffusion preventing film 106 of SiCN was formed on the Cu interconnect 105 to a thickness of 35 nm. A photoresist formed on the diffusion preventing film 106 was used to pattern etching solution injection inlets 107 (FIG. 3F). The layout of the etching solution injection inlets 107 was such that the injection inlet 107 was formed at a distance ΔD of 0.8 μm from the boundary. The diameter (d1) of the injection inlet 107 was 100 nm. The pitch (FIG. 7, d2) between the injection inlets 107 was 1 μm. The layout was made so that the distance between the injection inlet and the Cu interconnect 105 was 30 nm or greater. Lithography was performed, in which misregistration of the injection inlets 107 with respect to the Cu interconnect 105 was controlled to 20 nm at maximum. The etching solution injection inlets 107 were formed by dry etching (FIG. 3F), then the photoresist was removed. HF with a ratio of 1:200 by weight was injected through the surface of the wafer to form air gaps 108 to a depth of approximately 70 nm (FIG. 4G). Then, an upper interconnect layer was formed (FIG. 4H). The upper insulator film 102b was BD2x with a thickness of 200 nm. The vias were 50 nm in diameter (φ) and 90 nm in height. The height of the interconnect was 115 nm. The layout of the vias 110 was controlled so that registration was 30 nm at maximum with respect to the layer immediately below the vias 110 and the air gap formation layer and lithography was performed. The layout of the upper-layer interconnects 105b was controlled so that misregistration was 30 nm at maximum with respect to the interconnect layer immediately below the upper-layer interconnects 105b and the etching solution injection inlets 107 and lithography was performed. Vias 101 near the boundary with an air gap 108 among the vias 110 in region 1 where an air gap is not formed were laid out at a distance of 30 nm or greater from the boundary.

### Second Practical Example

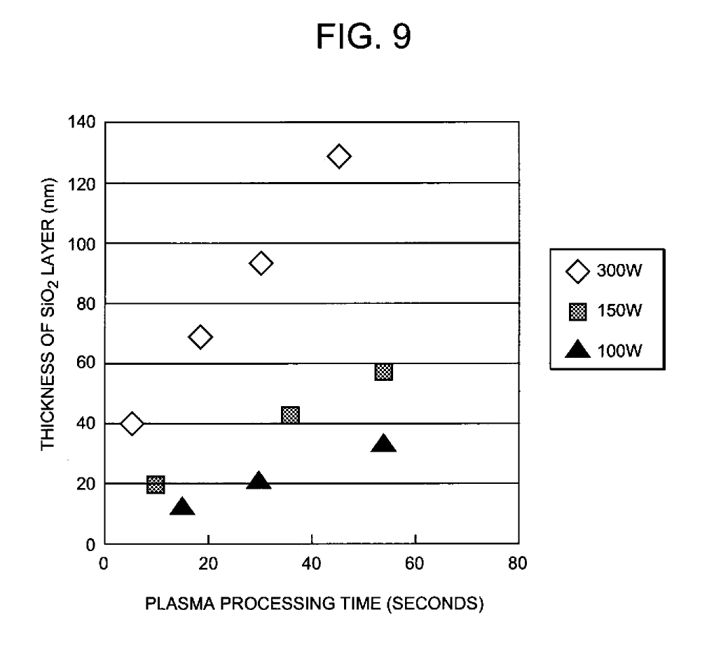

The plasma processing (FIG. 2C) of the first practical example was performed with different applied powers for different process times, and the relationship of the depth of an air gap 108 with applied power and process time was studied. The plasma processing was performed under the same conditions as in the first practical example except that the applied power (100 W, 150 W, and 300 W) and process time were changed. FIG. 9 shows the results. The vertical axis in FIG. 9 represents the thickness of the insulator film 102 immediately below the bottom of the air gap 108 (Δx in FIG. 4G).

### Third Practical Example

The plasma processing (FIG. 2C) of the first practical example was performed with different plasma sources for different plasma processing times and the relationship of the depth of an air gap 108 with the plasma source and plasma processing time was studied. With consideration given to the stability of plasma, the process was performed under the following fixed conditions. The rest of the example was the same as the first practical example.

### Processing Using Helium

Power: 440 W; flow rate: 5200 sccm; gas pressure: 1067 Pa (8.0 Torr); temperature: 335° C., distance between electrodes: 430 mils

### Processing Using Argon

Power: 600 W; flow rate: 400 sccm; gas pressure: 867 Pa (6.5 Torr); temperature: 335° C.; distance between electrodes: 350 mils

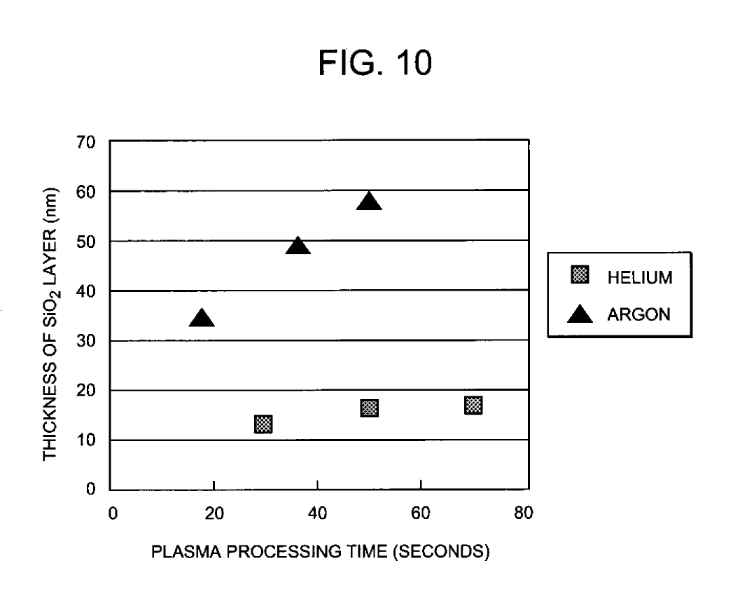

FIG. 10 shows the results. The vertical axis in FIG. 10 represents the thickness of the insulator film 102 immediately below the bottom of the air gap 108 (Δx in FIG. 4G). It can be seen from the results that the use of helium gas as the plasma source is especially effective in controlling the depth of the air gap 108 to a small value.

### Fourth Practical Example

The plasma processing (FIG. 2C) of the first practical example was performed using different types of insulator films 102 for different plasma processing times and the relationship of the depth of an air gap 108 with the type of the insulator film 102 and plasma processing time was studied. The following types of insulator films 102 were used. The rest of the process was the same as the first practical example.
BD (from Applied Materials, Inc.)
Porous SiCOH (p-SiCOH) formed in a plasma enhanced CVD system (Producer from Applied Materials, Inc.)
Cyclic siloxane films formed using OMCTS (Octamethylcyclotetrasiloxane) gas in the plasma enhanced CVD system (Producer from Applied Materials, Inc.)
Aurora (registered trademark, from Applied Materials, Inc.)

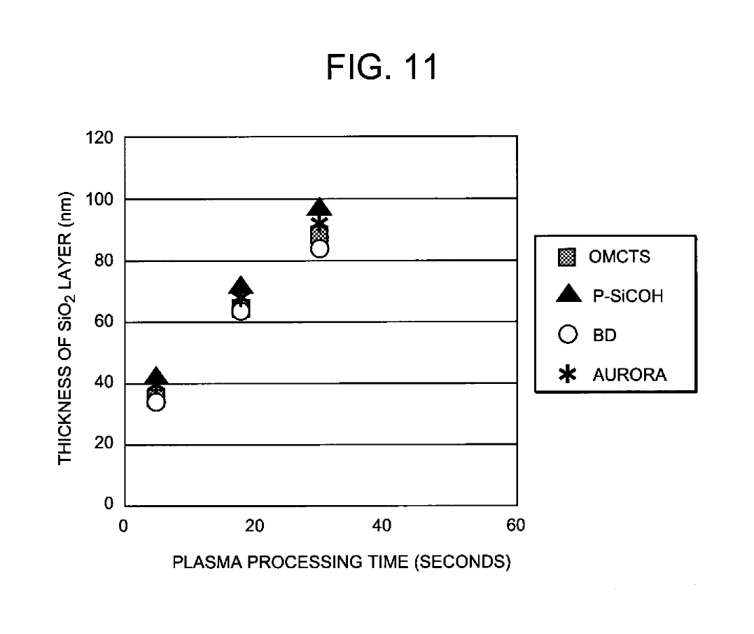

FIG. 11 shows the results. The vertical axis in FIG. 11 represents the thickness of the insulator film 102 immediately below the bottom of the air gap 108 (Δx in FIG. 4G). It can be seen from the results that the type of insulator film 102 can be relatively flexibly chosen according to the properties of the Cu interconnect 105 formed in region 1 where no air gap 108 is formed.

The embodiments of the present invention were described above with reference to the drawings. However, these embodiments are illustrative of the present invention and it is possible to adopt various configurations other than those described above. Also, a method of realizing the present invention is disclosed below in the present invention.

Alternative embodiments of the present invention are given below.
(1) A region where an air gap is to be formed and a region where an air gap is not to be formed are provided in the same interconnect layer of Cu interconnects.
(2) An interlayer insulator film in the region of the interconnect layer formed in (1) in which an air gap is not to be formed has a structure bridged with Si—O bonds, includes Si—C bonds, and considerably resists an etching solution such as hydrofluoric acid unless plasma processing is applied to the film.
(3) The depth of the air gap described in (1) is smaller than the thickness of the interlayer insulator film.
(4) In a method for forming the air gap between interconnect layers described in (2), a thin film having a high affinity for a photoresist is formed on the insulator film, is then coated with the photoresist, then exposure and development is performed to pattern the region where an air gap is to be formed, and plasma processing is performed in the direction vertical to the wafer.
(5) In a method for forming the air gap between the interconnect layers described in (2), chemical injection inlets are patterned in a Cu diffusion preventing insulator film formed on the interlayer insulator film in the region where the air gap is to be formed, and then a chemical that dissolves the insulator film is injected through the injection inlets to dissolve the insulator film.
(6) The insulator film described in (2) is a SiOC film having a k-value of less than or equal to 2.7.
(7) The thickness of the film formed on the insulator film that has a high affinity for the photoresist described in (4) is less than or equal to 50 nm.
(8) The film formed on the insulator film that has a high affinity for the photoresist described in (4) is a SiO₂ film is formed at a controlled temperature of 250° C. or lower.
(9) The film formed on the insulator film that has a high affinity for the photoresist described in (4) is a SiC film or SiCN film.
(10) The photoresist used in (4) has a density higher than the interlayer insulator film.
(11) The resist used in (4) has a thickness greater than air gaps to be formed.
(12) The plasma processing in (5) is performed by using a plasma source that is highly chemically unreactive with the insulator film, such as NH₃, He, Ne, or Ar.
(13) The chemical used in (5) is hydrofluoric acid or a solution of a salt of hydrofluoric acid.
(14) The fluorine content of the chemical used in (13) is greater than or equal to 0.5% of the solution in mole percentage.
(15) The chemical injection inlets formed in (5) are disposed at intervals of 1 μm or less.
(16) The chemical injection inlets formed in (5) are disposed at a distance between or equal to 0.5 μm and 1 μm from the boundary with the region where an air gap is not to be formed.
(17) The injection inlet is disposed in such a manner that the distance between one end of the injection inlet and the end of the interconnect that is closest to the injection inlet is greater than or equal to 30 nm so that the interconnect disposed in the region where an air gap is to be formed does not come into contact with the chemical injected in (5).
(18) The injection inlet is disposed in such a manner that the distance between one end of the injection inlet and the end of the interconnect that is closest to the injection inlet is greater than the sum of the maximum amount of misalignment with a lower-layer interconnect that can occur during patterning of the chemical injection inlet, a half of the difference between a design value of the diameter of the chemical injection inlet and the maximum diameter of the chemical injection inlet that can be provided, and a half of the difference between a design value of the width of the interconnect and the maximum width of the interconnect that can be provided, so that the interconnect disposed in the region where an air gap is to be formed does not come into contact with the chemical injected in (5).
(19) The injection inlet is disposed in such a manner that the distance between one end of the injection inlet and the end of the interconnect that is closest to the injection inlet is greater than or equal to 30 nm so that the interconnect formed in the layer formed on the interconnect layer in which an air gap is to be formed does not come into contact with the chemical injected in (5).
(20) The injection inlet is disposed in such a manner that the distance between one end of the injection inlet and the end of the interconnect that is closest to the injection inlet is greater than the sum of the maximum amount of misalignment with the chemical injection inlet that can occur during patterning of an upper-layer interconnect, a half of the difference between a design value of the diameter of the chemical injection inlet and the maximum diameter of the injection inlet that can be provided, and a half of the difference between a design value of the width of the upper-layer interconnect and the maximum width of the interconnect that can be provided, so that the interconnect formed in the layer on the interconnect layer in which an air gap is to be formed does not come in contact with the chemical injected in (5).
(21) The diameter of the chemical injection inlet formed in (5) does not exceed 0.9 times the thickness of the interlayer insulator film to be formed on a Cu diffusion barrier insulator film formed on the interconnect layer in which an air gap is to be formed.
(22) The diameter of the chemical injection inlet formed in (5) does not exceed 0.9 times the thickness of the interlayer insulator film to be formed on a Cu diffusion barrier insulator film formed on the interconnect layer in which an air gap is to be formed.
(23) A via for connecting the interconnect disposed in the region in which an air gap is to be formed as described in (1) to an interconnect in the layer immediately above the interconnect is disposed in such a manner that the distance between one end of the via and the end of the interconnect disposed in the region in which an air gap is to be formed that is closest to the end of the via is greater than or equal to 30 nm, so that all regions of the bottom of the via come into contact with a lower-layer interconnect.
(24) A via for connecting the interconnect disposed in the region in which an air gap is to be formed as described in (1) to an interconnect in the layer immediately above the interconnect is disposed in such a manner that the distance between one end of the via and the end of the interconnect disposed in the region in which an air gap is to be formed that is closes to the end of the via is greater than the sum of the maximum amount of misalignment with the lower-layer interconnect that can occur during patterning of the via, a half of the difference between a design value of the diameter of the via and the maximum diameter of the via that can be provided, and a half of the difference between a design value of the width of the interconnect and the maximum width of the interconnect that can be provided, so that all regions of the bottom of the via come into contact with a lower-layer interconnect.
(25) The end of a via for connecting an interconnect disposed in the region in which an air gap is not to be formed as described in (1) to an interconnect immediately above the interconnect that is closest to the boundary with the region where an air gap is to be formed is at a distance of at least 30 nm from the boundary.
(26) A via for connecting an interconnect disposed in the region where an air gap is not formed as described in (1) to an interconnect in the layer immediately above the interconnect is disposed in such a manner that the distance between the end of the via that is closest to the boundary with the region where an air gap is to be formed and the boundary is greater than the sum of the maximum value of misalignment with the chemical injection inlet that can occur during patterning of the via and a half of the difference between a design value of the diameter of the via and the maximum diameter of the via that can be provided.
(27) In the plasma processing described in (4), the depth of air gaps can be flexibly controlled with respect to the height of the interconnect by properly controlling conditions such as the applied power in the plasma processing, the plasma source, and process time according to the type of the interlayer insulator film to be processed.
(28) If there is an interconnect that is entirely contained within the region where an air gap is to be formed as described in (1), the depth of the air gap is smaller than the height of the interconnect.
(29) If all of the Cu interconnects described in (1) are disposed across both of the region where an air gap is not to be formed and the region where an air gap is to be formed described in (1), the depth of the air gaps is greater than the height of the interconnects as long as the length of any of the interconnects that is in the region where an air gap is not to be formed is greater than or equal to 10% of the entire length of the interconnect, at least two portions at both ends of the interconnect are in the region where an air gap is not to be formed, and an interconnect that is bridged across any two regions where an air gap is not to be formed and is disposed in the region where an air gap is to be formed is linear in shape.
(30) If all of the Cu interconnects described in (1) are disposed across both of the region where an air gap is not to be formed and the region where an air gap is to be formed described in (1), the depth of the air gap is greater than the height of the interconnects as long as at least two portions at both ends of the interconnect that are within any 10-μm range of the length of the interconnect are in the region where an air gap is not to be formed, the portions are greater than or equal to 0.5 μm in length, and the interconnect that is bridged across any two regions where an air gap is not to be formed and is disposed in the air gap region is linear in shape.
(31) The air gap region described in (1) is designed in such a manner that the air gap region is not disposed immediately below a bonding pad to be formed in the interconnect above the air gap region.
(32) The Cu diffusion preventing insulator film described in (5) is a SiC or SiCN film.

1. A method of making a semiconductor device, comprising:
forming a mask on an insulator film overlying a substrate;
removing the mask from a first region of the insulator film while leaving the mask in a second region of the insulator film;
exposing the first region to a plasma while the mask shields the second region, so as to render the first region more susceptible to removal by a subsequent treatment;
removing the mask film from the second region;
forming at least one metal interconnect in each of the first and second regions; and
selectively removing the first region to form an air gap adjacent a metal interconnect formed in the first region, while preserving the second region.

2. The method according to claim 1, wherein said selectively removing step comprises:
forming a diffusion preventing film on the insulator film;
forming an opening in a portion of the diffusion preventing film overlying the first region to expose the first region; and
removing the exposed first region by etching.

3. The method according to claim 2, wherein the diffusion preventing film is a SiCN film or a SiC film.

4. The method according to claim 2, wherein the insulator film is exposed so that a distance between a periphery of the opening and a boundary between the first and second regions is from 0.5 μm to 1.0 μm.

5. The method according to claim 1, wherein the plasma is generated from a gas selected from the group consisting of ammonium, helium, neon and argon.

6. The method according to claim 1, wherein the first region is selectively removed using an etching solution containing a hydrofluoric acid or a salt of hydrofluoric acid.

7. The method according to claim 1, wherein the insulator film includes Si—O bonds and Si—C bonds.

8. The method according to claim 1, further comprising the steps of:
forming an interconnect layer on the insulator film; and
forming an electrode pad in an upper region of said interconnect layer.
